(19) United States
(12) Patent Application Publication
(10) Pub. No.: US 2026/0180041 A1
(43) Pub. Date: Jun. 25, 2026

(54) DETECTION SYSTEM AND DETECTION METHOD

(71) Applicant: HIOKI E.E. CORPORATION, Nagano (JP)

(72) Inventors: Takayuki TERASHIMA, Nagano (JP); Yuta SUZUKI, Nagano (JP)

(21) Appl. No.: 19/113,269

(22) PCT Filed: Sep. 6, 2023
(86) PCT No.: PCT/JP2023/032534

§ 371 Date: Mar. 19, 2025

(30) Foreign Application Priority Data
Sep. 20, 2022 (JP) 2022-149275
Sep. 5, 2023 (JP) 2023-143973

(51) Int. Cl. H01M 10/42; H01M 10/052; H01M 10/0525; H01M 50/503; H01M 50/536

(52) U.S. Cl. CPC H01M 10/425; H01M 10/052; H01M 10/0525; H01M 50/503; H01M 50/536

(57) ABSTRACT

A detection system 1 detects connection quality of a connection part where a plurality of electrode tabs and external electrodes are connected in a wound battery A, and includes a power feed unit 22 that supplies a current between a positive electrode tab B11 of the wound battery A and a negative electrode tab C11 of the wound battery A, a detection unit 4 that detects a magnetic field resulting from current supply to the wound battery A, and a processing unit 24 that determines connection quality of the connection part based on a magnitude of the magnetic field.

### TECHNICAL FIELD

The present invention relates to a detection system and a detection method for detecting connection quality of electrode tabs of a wound battery.

### BACKGROUND ART

JP 2002-008709 A discloses a wound battery formed by winding a layered structure of a positive electrode and a negative electrode provided with the electrode active materials formed on a strip collector through a separator interposed between them.

In the invention described in JP 2002-008709 A, a connection defect is likely to be generated when a plurality of electrode tabs (specifically, a positive electrode tab and a negative electrode tab) are connected to an external electrode.

As a known method for detecting such a connection defect, an internal resistance of a wound battery is detected, and connection quality is determined by the detected internal resistance.

### SUMMARY OF INVENTION

However, in the known detection method, the ratio of the contact resistance of the electrode in the internal resistance of the wound battery is extremely small, and therefore there is a problem that a connection defect cannot be accurately detected.

Therefore, the present invention has been made in view of the above problem, and an object is to provide a detection system and a detection method that can accurately detect connection quality of an electrode tab of a wound battery.

According to one aspect of the present invention, provided is a detection system that detects connection quality of a connection part where a plurality of electrode tabs and external electrodes are connected in a wound battery, the detection system including: a power feed unit or a power discharge unit configured to perform power feed or power discharge between a positive electrode tab of the wound battery and a negative electrode tab of the wound battery; a detection unit configured to detect a magnetic field-related parameter resulting from power feed to the wound battery or power discharge from the wound battery; and a processing unit configured to determine connection quality of the connection part based on the magnetic field-related parameter that is detected.

According to another aspect of the present invention, provided is a detection method for detecting connection quality of a connection part where a plurality of electrode tabs and external electrodes are connected in a wound battery, the detection method including: a power feed or power discharge step of performing power feed or power discharge between a positive electrode tab of the wound battery and a negative electrode tab of the wound battery; a detection step of detecting a magnetic field-related parameter resulting from power feed to the wound battery or power discharge from the wound battery; and a determination step of determining connection quality of the connection part based on the magnetic field-related parameter that is detected.

According to an aspect of the present invention, it is possible to accurately detect connection quality of a connection part where a plurality of electrode tabs and external electrodes of a wound battery are connected.

### BRIEF DESCRIPTION OF DRAWINGS

FIG. 1 is a schematic cross-sectional view illustrating a configuration of a wound battery according to a first embodiment.

FIG. 2 is a schematic explanatory diagram illustrating each configuration of a detection system according to the first embodiment.

FIG. 3 is a block diagram illustrating each configuration of a detection device constituting the detection system according to the first embodiment.

FIG. 4 is a flowchart showing each step of a detection method by the detection system according to the first embodiment.

FIG. 5A is a schematic development view illustrating a connection defect of a single positive electrode tab positioned on an outermost peripheral side of a connection part where a plurality of electrode tabs and external electrodes are connected in a wound battery.

FIG. 5B is a schematic perspective view illustrating a connection defect of the single positive electrode tab positioned on the outermost peripheral side of the connection part where the plurality of electrode tabs and external electrodes are connected in the wound battery.

FIG. 6A is a schematic development view illustrating a connection defect of a plurality of positive electrode tabs positioned on an outer peripheral side of the connection part where the plurality of electrode tabs and external electrodes are connected in the wound battery.

FIG. 6B is a schematic perspective view illustrating a connection defect of the plurality of positive electrode tabs positioned on the outer peripheral side of the connection part where the plurality of electrode tabs and external electrodes are connected in the wound battery.

FIG. 7A is a schematic development view illustrating a connection defect of a single negative electrode tab positioned on an innermost peripheral side of the connection part where the plurality of electrode tabs and external electrodes are connected in the wound battery.

FIG. 7B is a schematic perspective view illustrating a connection defect of the single negative electrode tab positioned on the innermost peripheral side of the connection part where the plurality of electrode tabs and external electrodes are connected in the wound battery.

FIG. 8A is a schematic development view illustrating a connection defect of a plurality of negative electrode tabs positioned on an inner peripheral side of the connection part where the plurality of electrode tabs and external electrodes are connected in the wound battery.

FIG. 8B is a schematic perspective view illustrating a connection defect of the plurality of negative electrode tabs positioned on the inner peripheral side of the connection part where the plurality of electrode tabs and external electrodes are connected in the wound battery.

FIG. 9 is a schematic explanatory diagram illustrating each configuration of a detection system according to a modification.

FIG. 10A is a schematic development view illustrating a connection defect of a single negative electrode tab positioned on an outermost peripheral side of a connection part where a plurality of electrode tabs and external electrodes are connected in the wound battery of the modification.

FIG. 10B is a schematic perspective view illustrating a connection defect of the single negative electrode tab positioned on the outermost peripheral side of the connection part where the plurality of electrode tabs and external electrodes are connected in the wound battery of the modification.

FIG. 11A is a schematic development view illustrating a connection defect of a plurality of negative electrode tabs positioned on the outermost peripheral side of the connection part where the plurality of electrode tabs and external electrodes are connected in the wound battery of the modification.

FIG. 11B is a schematic perspective view illustrating a connection defect of the plurality of negative electrode tabs positioned on the outermost peripheral side of the connection part where the plurality of electrode tabs and external electrodes are connected in the wound battery of the modification.

FIG. 12 is a schematic explanatory diagram illustrating each configuration of a detection system according to a second embodiment.

FIG. 13 is a flowchart showing each step of a detection method by the detection system according to the second embodiment.

FIG. 14 is a flowchart showing each step of a detection method according to a modification of the second embodiment.

FIG. 15 is a schematic explanatory diagram illustrating each configuration of a detection system according to a third embodiment.

FIG. 16 is a schematic explanatory diagram illustrating an example of a plurality of detection points according to the third embodiment.

FIG. 17 is a flowchart showing each step of a detection method by the detection system according to the third embodiment.

FIG. 18 is a comparison graph showing three of an ideal characteristic graph, a good product characteristic graph, and a defective product characteristic graph.

FIG. 19 is an explanatory diagram illustrating an example of calculation of a matching degree.

### DESCRIPTION OF EMBODIMENTS

Embodiments for carrying out the present invention will be described below with reference to the accompanying drawings. In the present description, identical elements are given identical reference signs throughout.

### First Embodiment

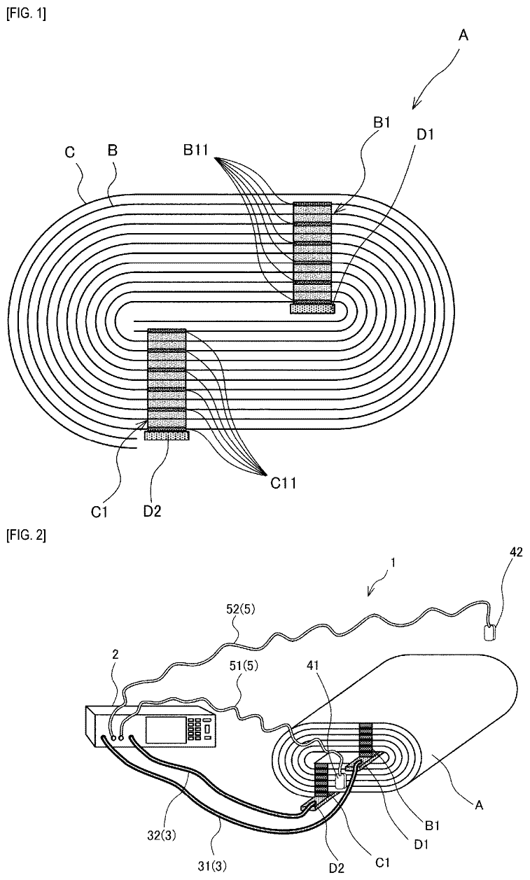

Hereinafter, a wound battery A, a detection system 1, and a detection method according to the first embodiment will be described with reference to FIGS. 1 to 11B.

### [Configuration of Wound Battery]

First, the configuration of the wound battery A as a detection target according to the first embodiment will be described with reference to FIG. 1.

FIG. 1 is a schematic cross-sectional view illustrating the configuration of the wound battery A according to the first embodiment.

As illustrated in FIG. 1, the wound battery A according to the first embodiment is a lithium ion battery in which a positive electrode layer B having a sheet shape and a negative electrode layer C having a sheet shape are layered via a separator (not illustrated) as an insulator and wound. The wound battery A is sealed in a case (not illustrated) and used. Note that the separator prevents a short circuit between the positive electrode layer B and the negative electrode layer C, but allows electron transfer between the positive electrode layer B and the negative electrode layer C.

The wound battery A includes a positive electrode tab group B1 provided at one end and a negative electrode tab group C1 provided at one end so as not to interfere with the positive electrode tab group B1 (i.e., separate from the positive electrode tab group B1). The positive electrode tab group B1 is formed by joining (specifically, welding) a plurality of positive electrode tabs B11 provided so as to protrude from one end of each positive electrode layer B that is wound and to align along a thickness direction of the wound battery A. Similarly, the negative electrode tab group C1 is formed by joining (specifically, welding) a plurality of negative electrode tabs C11 provided so as to protrude from one end of each negative electrode layer that is wound and to align along the thickness direction of the wound battery A.

By being joined (specifically, welded), the positive electrode tab group B1 and the negative electrode tab group C1 are connected respectively to a first external electrode D1 having a sheet shape as an external electrode and a second external electrode D2 having a sheet shape as an external electrode. In the first embodiment, an upper surface as one surface of the first external electrode D1 and an upper surface as one surface of the second external electrode D2 are connected respectively to a lower surface of the positive electrode tab B11 positioned on the innermost peripheral side of the positive electrode tab group B1 and a lower surface of the negative electrode tab C11 positioned on the outermost peripheral side of the negative electrode tab group C1.

A connection defect is likely to be generated at a connection part where a plurality of electrode tabs (specifically, the positive electrode tab B11 and the negative electrode tab C11) and external electrodes (specifically, the first external electrode D1 and the second external electrode D2) in the wound battery A are connected by joining (e.g., welding). Therefore, as a result of intensive research by the inventor, the detection system 1 (see FIG. 2) that can accurately detect connection quality of such a connection part and the detection method by the detection system 1 have been invented. Note that details of the detection system 1 and the detection method will be described later.

### [Configuration of Detection System]

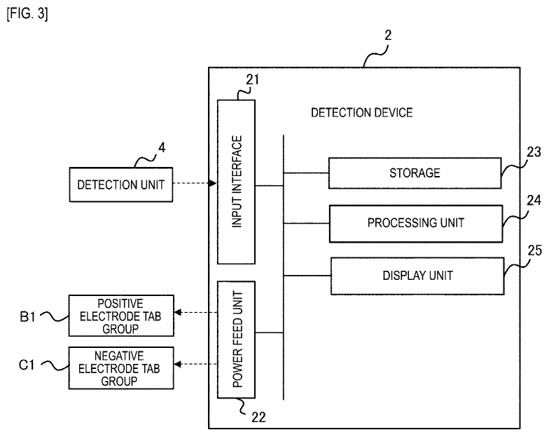

Next, the detection system 1 according to the first embodiment will be described with reference to FIGS. 2 and 3.

FIG. 2 is a schematic explanatory diagram illustrating each configuration of the detection system 1 according to the first embodiment. FIG. 3 is a block diagram illustrating each configuration of a detection device 2 constituting the detection system 1 according to the first embodiment.

As illustrated in FIG. 2, the detection system 1 according to the first embodiment is a system that detects connection quality of a connection part where a plurality of electrode tabs (specifically, the positive electrode tab B11 and the negative electrode tab C11) and external electrodes (specifically, the first external electrode D1 and the second external electrode D2) are connected in the wound battery A. The detection system 1 includes the detection device 2, a current wiring 3, a detection unit 4, and a detection wiring 5.

As illustrated in FIG. 3, the detection device 2 includes an input interface 21, a power feed unit 22, a storage 23, a processing unit 24, and a display unit 25 as a notification unit. In the first embodiment, the power feed unit 22, the storage 23, the processing unit 24, and the display unit 25 are formed so as to be incorporated in the detection device 2, but are not limited to this, and may be formed separately from one another, for example. When the power feed unit 22, the storage 23, the processing unit 24, and the display unit 25 are incorporated in the detection device 2, the entire detection system 1 can be simplified.

A detection result detected by the detection unit 4 is input to the input interface 21. The input interface 21 outputs the detection result from the detection unit 4 to the processing unit 24.

The power feed unit 22 supplies a current (specifically, a predetermined direct current stored in the storage 23 in advance) between the positive electrode tab group B1 (i.e., the plurality of positive electrode tabs B11) of the wound battery A and the negative electrode tab group C1 (i.e., the plurality of negative electrode tabs C11) of the wound battery A via the first external electrode D1 and the second external electrode D2.

The storage 23 stores a processing program and an algorithm program to be executed in the processing unit 24. The storage 23 temporarily stores the detection result detected by the detection unit 4 via the input interface 21. In the first embodiment, the storage 23 is provided separately from the processing unit 24, but is not limited to this, and may be incorporated in the processing unit 24.

Furthermore, the storage 23 stores the predetermined direct current supplied between the positive electrode tab group B1 of the wound battery A and the negative electrode tab group C1 of the wound battery A, a predetermined threshold used for determination processing of connection quality by the processing unit 24, and a table used for identification processing of an electrode tab with a connection defect. Note that the table includes a magnitude range of a plurality of magnetic fields, an orientation (positive or negative) of a magnetic field corresponding to the magnitude range of the plurality of magnetic fields, and a plurality of electrode tabs with connection defects corresponding to both.

The processing unit 24 determines connection quality of the connection part (specifically, the electrode tab) based on the detection result from the detection unit 4, and outputs the determination result to the display unit 25. Then, when determining that the connection of the connection part is defective, the processing unit 24 identifies the electrode tab with a connection defect and outputs the identification result to the display unit 25. In the first embodiment, the processing unit 24 includes a CPU as a computer, but is not limited to this, and may include, for example, a plurality of microcomputers. Note that details of the processing unit 24 will be described later.

The display unit 25 is a means for notifying the determination result output from the processing unit 24 or a display for displaying the determination result. In the first embodiment, the notification unit includes the display unit 25, but is not limited to this, and may include, for example, a speaker.

Returning to FIG. 2, the current wiring 3 includes a first current wiring 31 connecting the power feed unit 22 of the detection device 2 and the positive electrode tab group B1 (i.e., the plurality of positive electrode tabs B11), and a second current wiring 32 connecting the power feed unit 22 and the negative electrode tab group C1 (i.e., the plurality of negative electrode tabs C11).

The first current wiring 31 has one end connected to one end of the power feed unit 22, and the other end connected to the positive electrode tab group B1 via the first external electrode D1. Similarly, the second current wiring 32 has one end connected to the other end of the power feed unit 22, and the other end connected to the negative electrode tab group C1 via the second external electrode D2.

From the viewpoint of suppressing generation of an external magnetic field, the first current wiring 31 and the second current wiring 32 preferably include a magnetic shield wiring. In this case, it is not necessary to separately provide another magnetic shielding means, and the entire detection system 1 can be simplified. On the other hand, the first current wiring 31 and the second current wiring 32 may include not the magnetic shield wiring but a four-terminal pair measurement structure wiring, a twist wiring, or a coaxial wiring.

The detection unit 4 detects a magnetic field as a magnetic field-related parameter by current supply to the wound battery A. The detection unit 4 includes a first detection sensor 41 as a first detection unit that is provided in proximity to the wound battery A and detects a first magnetic field as a magnetic field (specifically, a magnetic field including an external magnetic field), and a second detection sensor 42 as a second detection unit that is provided farther away from the wound battery A than the first detection sensor 41 and detects a second magnetic field as an external magnetic field.

The first detection sensor 41 is a sensor that detects the first magnetic field in an axial direction of the wound battery A, and the second detection sensor 42 is a sensor that detects the second magnetic field in the axial direction of the wound battery A. This can suppress generation of noise due to the external magnetic field or the like and improve detection accuracy, and therefore it is possible to more accurately detect connection quality of the connection part.

The first detection sensor 41 and the second detection sensor 42 are provided on one end side or the other end side of the wound battery A. This can accurately detect the first magnetic field and the second magnetic field due to the current flowing in the winding direction of the wound battery A, and therefore it is possible to more accurately detect connection quality of the connection part. In the first embodiment, the first detection sensor 41 and the second detection sensor 42 are provided respectively on one end side (i.e., the side provided with the electrode tab) of the wound battery A and the other end side (i.e., the side not provided with the electrode tab) of the wound battery A.

The detection wiring 5 is a wiring connecting the detection unit 4 and the processing unit 24. Specifically, the detection wiring 5 includes a first detection wiring 51 connecting the first detection sensor 41 and the processing unit 24, and a second detection wiring 52 connecting the second detection sensor 42 and the processing unit 24.

From the viewpoint of difficulty in picking up a magnetic field from the outside, the first detection wiring 51 and the second detection wiring 52 preferably include a magnetic shield wiring. In this case, it is not necessary to separately provide another magnetic shielding means, and the entire detection system 1 can be simplified. On the other hand, the first detection wiring 51 and the second detection wiring 52 may include not the magnetic shield wiring but a four-terminal pair measurement structure wiring, a twist wiring, or a coaxial wiring.

### [Detection Method by Detection System]

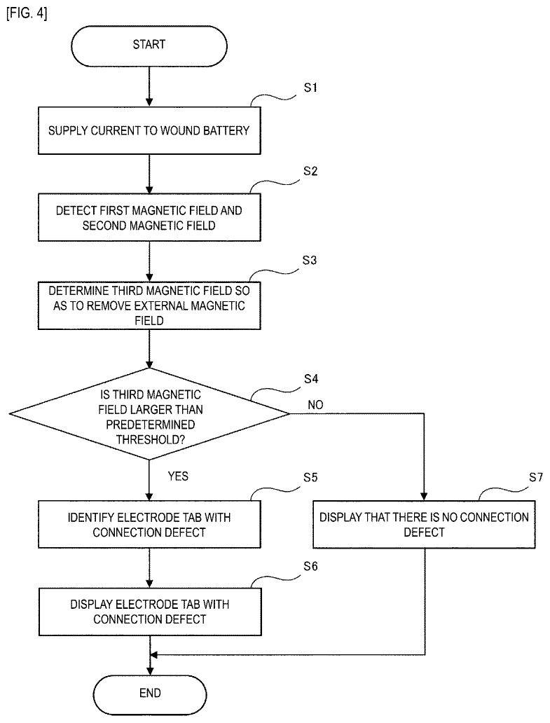

Next, a detection method according to the first embodiment will be described with reference to FIGS. 4 to 8B.

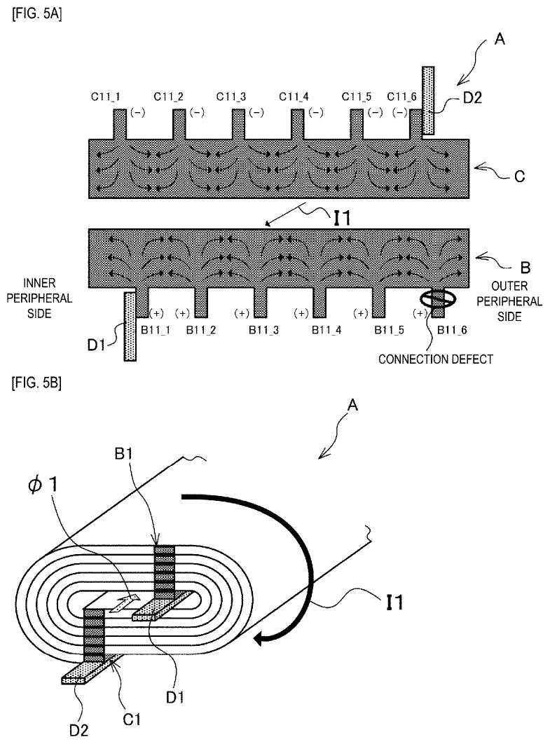

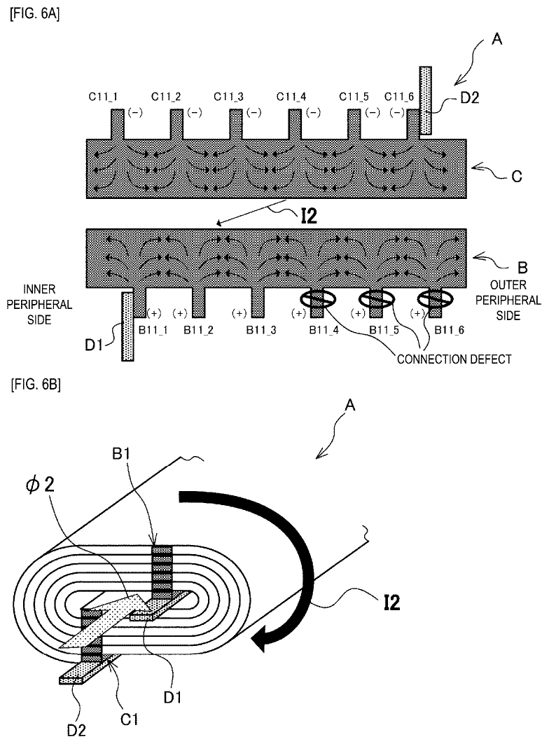

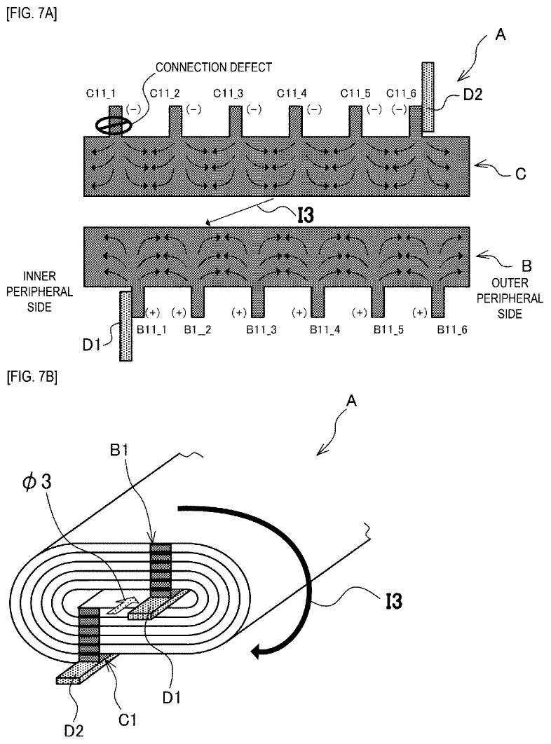

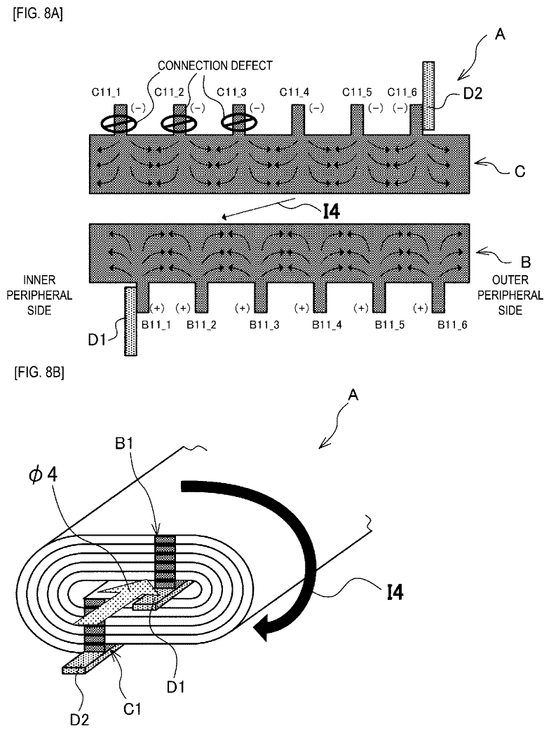

FIG. 4 is a flowchart showing each step of the detection method by the detection system 1 according to the first embodiment. FIG. 5A is a schematic development view illustrating a connection defect of a single positive electrode tab B116 positioned on the outermost peripheral side of the connection part where the plurality of electrode tabs and external electrodes are connected in the wound battery A. FIG. 5B is a schematic perspective view illustrating a connection defect of the single positive electrode tab B11_1 positioned on the outermost peripheral side of the connection part where the plurality of electrode tabs and external electrodes are connected in the wound battery A. FIG. 6A is a schematic development view illustrating a connection defect of a plurality of positive electrode tabs B114 to B11_6 positioned on the outer peripheral side of the connection part where the plurality of electrode tabs and external electrodes are connected in the wound battery A. FIG. 6B is a schematic perspective view illustrating a connection defect of the plurality of positive electrode tabs B114 to B11_6 positioned on the outer peripheral side of the connection part where the plurality of electrode tabs and external electrodes are connected in the wound battery A. FIG. 7A is a schematic development view illustrating a connection defect of a single negative electrode tab C11_1 positioned on the innermost peripheral side of the connection part where the plurality of electrode tabs and external electrodes are connected in the wound battery A. FIG. 7B is a schematic perspective view illustrating a connection defect of the single negative electrode tab C11_1 positioned on the innermost peripheral side of the connection part where the plurality of electrode tabs and external electrodes are connected in the wound battery A. FIG. 8A is a schematic development view illustrating a connection defect of a plurality of negative electrode tabs C11_1 to C11_3 positioned on the inner peripheral side of the connection part where the plurality of electrode tabs and external electrodes are connected in the wound battery A. FIG. 8B is a schematic perspective view illustrating a connection defect of the plurality of negative electrode tabs C11_1 to C11_3 positioned on the inner peripheral side of the connection part where the plurality of electrode tabs and external electrodes are connected in the wound battery A. Note that as illustrated in FIGS. 5A, 6A, 7A, and 8A, as an example, the wound battery A in which the connection quality of the connection part is detected has six positive electrode tabs B11_1 to B11_6 and six negative electrode tabs C11_1 to C11_6 in order from the inner peripheral side to the outer peripheral side. As illustrated in FIGS. 5A, 6A, 7A, and 8A, arrows drawn in the positive electrode layer B and the negative electrode layer C indicate the orientations of electrons.

When the switch of the detection device 2 is switched from off to on by the user, each step of the detection method by the detection system 1 is executed.

As shown in FIG. 4, first, in step S1, the power feed unit 22 supplies a predetermined direct current between the positive electrode tabs B11 of the wound battery A and the negative electrode tabs C11 of the wound battery A via the current wiring 3, and the process proceeds to step S2. Then, if a connection defect in the connection part (specifically, the electrode tabs) is generated, the current flows in the winding direction of the wound battery A (see FIGS. 5B, 6B, 7B, and 8B), and therefore a magnetic field is generated around thereof. On the other hand, if a connection defect in the connection part (specifically, the electrode tabs) is not generated, the current does not flow in the winding direction of the wound battery A, or the current flowing in the winding direction of the wound battery A is weak, and therefore no magnetic field is generated around thereof.

Next, in step S2, the first detection sensor 41 and the second detection sensor 42 detect the first magnetic field and the second magnetic field, respectively, by the current flowing in the winding direction of the wound battery A. Then, the first detection sensor 41 and the second detection sensor 42 output the detected first magnetic field and second magnetic field to the processing unit 24 via the input interface 21, and the process proceeds to step S3.

Next, in step S3, the processing unit 24 removes the external magnetic field based on the first magnetic field and the second magnetic field respectively output from the first detection sensor 41 and the second detection sensor, and calculates a third magnetic field as a magnetic field only by the current flowing in the winding direction of the wound battery A, and the process proceeds to step S4.

In the first embodiment, in step S3, the processing unit 24 removes the external magnetic field based on the difference between the first magnetic field and the second magnetic field, and calculates the third magnetic field. This can remove the influence of the external magnetic field on determination of connection quality, and therefore it is possible to more accurately detect connection quality of the connection part. However, in step S3, the processing unit 24 is not limited to this, and for example, when the first detection sensor 41 and the second detection sensor 42 are provided respectively on one end side of the wound battery A and the other end side of the wound battery A, the processing unit 24 may remove the external magnetic field based on addition of the first magnetic field and the second magnetic field, and calculate the third magnetic field.

Next, in step S4, the processing unit 24 determines connection quality of the connection part (specifically, the plurality of positive electrode tabs B11 and the plurality of negative electrode tabs C11) based on the calculated third magnetic field.

Specifically, in step S4, the processing unit 24 determines contact quality of the connection part based on the magnitude (absolute value) of the third magnetic field and a predetermined threshold (value greater than zero) stored in the storage 23 in advance. Then, if the magnitude of the third magnetic field is greater than the predetermined threshold (case of Yes), the processing unit 24 determines that the connection of the connection part is defective, and the process proceeds to step S5. On the other hand, if the magnitude of the third magnetic field is the predetermined threshold or less (case of No), the processing unit 24 determines that the connection of the connection part is good, notifies the display unit 25 of the determined goodness of the connection part, and the process proceeds to step S7. By this, by using the magnetic field by the current flowing in the winding direction of the wound battery A for determination of connection quality of the connection part, it is possible to accurately detect the connection quality of the connection part regardless of measurement of the resistance value of the wound battery A.

Next, in step S5, the processing unit 24 identifies an electrode tab with a connection defect based on the magnitude of the third magnetic field and the orientation of the third magnetic field. Then, the processing unit 24 outputs the identifies electrode tab with the connection defect to the display unit 25, and the process proceeds to step S6.

Specifically, in step S5, the processing unit 24 identifies the electrode tab with a connection defect based on the magnitude of the third magnetic field, the orientation (positive or negative) of the third magnetic field, and the table stored in the storage 23 in advance. More specifically, in step S5, based on the magnitude of the third magnetic field, the orientation of the third magnetic field, and the table, the processing unit 24 identifies, from the table, the electrode tab with a connection defect that matches both the magnitude of the third magnetic field and the orientation of the third magnetic field. This makes it possible to easily identify the electrode tab with a connection defect.

As illustrated in FIGS. 5A and 5B, when a connection defect is generated in the positive electrode tab B116 positioned on the outermost peripheral side of the connection part where the plurality of electrodes and the external electrodes are connected in the wound battery A, a relatively small current I1 flowing in the clockwise direction (inner winding direction) of the wound battery A is generated, and a relatively small magnetic flux φ1 (i.e., the third magnetic field) in the axis positive direction of the wound battery A by the current I1 is generated. Note that here, the axis positive direction is a direction from one end side of the wound battery A toward the other end side of the wound battery A, and is also simply called a positive direction.

On the other hand, as illustrated in FIGS. 6A and 6B, when a connection defect is generated in the plurality of positive electrode tabs B11_4 to B11_6 positioned on the outer peripheral side of the connection part where the plurality of electrode tabs and the external electrodes are connected in the wound battery A, a current I2 greater than the current I1 flowing in the clockwise direction (inner winding direction) of the wound battery A is generated, and a magnetic flux φ2 (i.e., the third magnetic field) greater than the magnetic flux φ1 in the axis positive direction of the wound battery A by the current I2 is generated.

As illustrated in FIGS. 7A and 7B, when a connection defect is generated in the negative electrode tab C11_1 positioned on the innermost peripheral side of the connection part where the plurality of electrode tabs and the external electrodes are connected in the wound battery A, a relatively small current I3 flowing in the clockwise direction (inner winding direction) of the wound battery A is generated, and a relatively small magnetic flux φ3 (i.e., the third magnetic field) in the positive direction of the wound battery A due to the current I3 is generated.

On the other hand, as illustrated in FIGS. 8A and 8B, when a connection defect is generated in the plurality of negative electrode tabs C11_1 to C11_3 positioned on the inner peripheral side of the connection part where the plurality of electrode tabs and the external electrodes are connected in the wound battery A, a current I4 greater than the current I3 flowing in the clockwise direction (inner winding direction) of the wound battery A is generated, and a magnetic flux φ4 (i.e., the third magnetic field) greater than the magnetic flux φ3 in the positive direction of the wound battery A by the current I4 is generated.

Then, as illustrated in FIGS. 5A to 6B or FIGS. 7A to 8B, the processing unit 24 identifies that the electrode tab with a connection defect is closer to the external electrode as the third magnetic field is greater. This can substantially identify the position of the electrode tab with a connection defect among the plurality of aligned electrode tabs.

As illustrated in FIGS. 5A to 8B, the processing unit 24 identify whether the electrode tab with a connection defect is positive or negative based on the orientation of the third magnetic field. This makes it possible to easily identify positive or negative of the electrode tab with a connection defect.

Next, in step S6, the display unit 25 displays the electrode tab with a connection defect output from the processing unit 24, and ends the present processing. This enables the user to easily grasp generation of the connection defect and the electrode tab having a connection defect.

On the other hand, in step S7, the display unit 25 displays connection goodness of the connection part notified from the processing unit 24, and ends the present processing. This enables the user to easily grasp connection goodness of the connection part.

### Actions and Effects of First Embodiment

Next, main actions and effects according to the first embodiment will be described.

The detection system 1 according to the first embodiment is the detection system 1 that detects connection quality of a connection part where a plurality of electrode tabs and external electrodes are connected in the wound battery A, and includes the power feed unit 22 that performs power feed between the positive electrode tab B11 of the wound battery A and the negative electrode tab C11 of the wound battery A, the detection unit 4 that detects a magnetic field by power feed to the wound battery A, and the processing unit 24 that determines connection quality of the connection part based on the magnitude of the detected magnetic field.

The detection method according to the first embodiment is a detection method for detecting connection quality of a connection part where a plurality of electrode tabs and external electrodes are connected in the wound battery A, the detection method including: a power feed step of performing power feed between the positive electrode tab B11 of the wound battery A and the negative electrode tab C11 of the wound battery A; a detection step of detecting a magnetic field by power feed to the wound battery A; and a determination step of determining connection quality of the connection part based on the magnitude of the detected magnetic field.

According to these configurations, when due to power feed performed between the positive electrode tab B11 including the plurality of tabs of the wound battery A and the negative electrode tab C11 including the plurality of tabs of the wound battery A, a connection defect is generated at the connection part where the plurality of electrode tabs and the external electrodes are connected in the wound battery A, a current flowing in the winding direction of the wound battery A can be generated. Then, by detecting the magnetic field by the current flowing in the winding direction of the wound battery A and using the magnetic field for determination of connection quality of the connection part, it is possible to accurately detect the connection quality of the connection part regardless of measurement of the resistance value of the wound battery A.

In the first embodiment, the processing unit 24 determines that the connection of the connection part is good if the magnitude (absolute value) of the magnetic field is a predetermined threshold or less, and determines that the connection of the connection part is defective if the magnitude (absolute value) of the magnetic field is greater than the predetermined threshold.

According to this configuration, by using the predetermined threshold, it is possible to accurately detect the connection quality of the connection part.

In the first embodiment, the power feed unit 22 supplies a direct current between the positive electrode tab B11 of the wound battery A and the negative electrode tab C11 of the wound battery A, the detection unit 4 includes the first detection sensor 41 that is provided in proximity to the wound battery A and detects a magnetic field, and the second detection sensor 42 that is provided farther away from the wound battery A than the first detection sensor and detects an external magnetic field, and the processing unit 24 determines connection quality of the connection part based on the magnetic field and the external magnetic field that are detected.

According to this configuration, since it is possible to remove the influence of the external magnetic field on determination of connection quality, it is possible to more accurately detect connection quality of the connection part.

In the first embodiment, the detection system 1 further includes the current wiring 3 including a four-terminal pair measurement structure wiring, a twist wiring, a coaxial wiring, or a magnetic shield wiring, in which the power feed unit 22 and the positive electrode tab B11 or the negative electrode tab C11 are connected.

According to this configuration, it is possible to suppress generation of the external magnetic field, and therefore it is possible to more accurately detect connection quality of the connection part.

In the first embodiment, the detection system 1 further includes the detection wiring 5 including a four-terminal pair measurement structure wiring, a twist wiring, a coaxial wiring, or a magnetic shield wiring, in which the detection unit 4 and the processing unit 24 are connected.

According to this configuration, since it is difficult to pick up a magnetic field from the outside, it is possible to more accurately detect connection quality of the connection part.

In the first embodiment, the detection unit 4 detects the magnetic field generated by the current flowing in the winding direction of the wound battery A.

According to this configuration, since it is possible to suppress generation of noise due to the external magnetic field or the like and improve detection accuracy, it is possible to more accurately detect connection quality of the connection part.

In the first embodiment, when the magnitude of the detected magnetic field (magnetic field-related parameter) is greater than the predetermined threshold, the processing unit 24 identifies that the electrode tab with a connection defect is closer to the external electrode as the magnetic field (magnetic field-related parameter) is greater.

According to this configuration, it is possible to substantially identify the position of the electrode tab with a connection defect among the plurality of aligned electrode tabs.

In the first embodiment, when the magnitude of the detected magnetic field (magnetic field-related parameter) is greater than the predetermined threshold, the processing unit 24 identifies whether the electrode tab with a connection defect is positive or negative based on the orientation of the magnetic field (magnetic field-related parameter).

According to this configuration, it is possible to easily identify positive or negative of the electrode tab with a connection defect.

In the first embodiment, when the magnitude of the detected magnetic field (magnetic field-related parameter) is greater than the predetermined threshold, the processing unit 24 identifies the electrode tab with a connection defect based on the magnitude of the magnetic field (magnetic field-related parameter) and the orientation of the magnetic field (magnetic field-related parameter).

According to this configuration, it is possible to easily identify the electrode tab with a connection defect.

In the first embodiment, the power feed unit 22 and the processing unit 24 are integrally formed.

According to this configuration, the entire detection system 1 can be simplified.

### Modification of First Embodiment

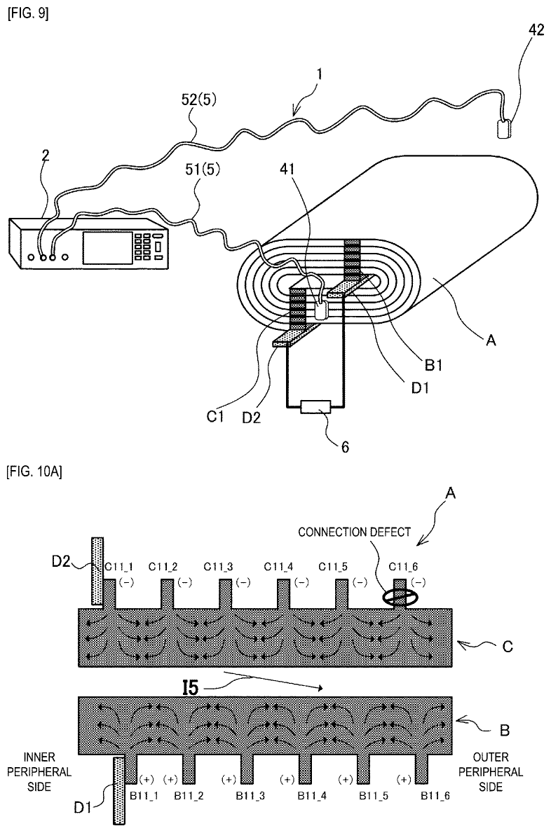

Next, the detection system 1 according to the modification will be described with reference to FIGS. 9 to 11B.

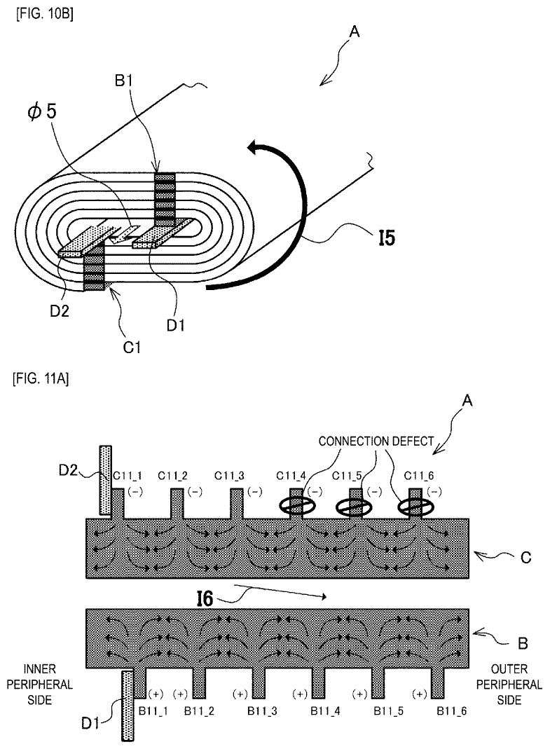

FIG. 9 is a schematic explanatory diagram illustrating each configuration of the detection system 1 according to the modification. FIG. 10A is a schematic development view illustrating a connection defect of a negative electrode tab C11_6 positioned on the outermost peripheral side of a connection part where a plurality of electrode tabs and external electrodes are connected in the wound battery A of the modification. FIG. 10B is a schematic perspective view illustrating a connection defect of the negative electrode tab C11_6 positioned on the outermost peripheral side of the connection part where the plurality of electrode tabs and external electrodes are connected in the wound battery A of the modification. FIG. 11A is a schematic development view illustrating a connection defect of a plurality of negative electrode tabs C11_4 to C11_6 positioned on the outermost peripheral side of the connection part where the plurality of electrode tabs and external electrodes are connected in the wound battery A of the modification. FIG. 11B is a schematic perspective view illustrating a connection defect of the plurality of negative electrode tabs C11_4 to C11_6 positioned on the outermost peripheral side of the connection part where the plurality of electrode tabs and external electrodes are connected in the wound battery A of the modification. Note that as illustrated in FIGS. 10A and 11A, as an example, the wound battery A in which the connection quality of the connection part is detected has six positive electrode tabs B11_1 to B116 and six negative electrode tabs C11_1 to C11_6 in order from the inner peripheral side to the outer peripheral side. As illustrated in FIGS. 10A and 11A, arrows drawn in the positive electrode layer B and the negative electrode layer C indicate the orientations of electrons. Furthermore, in the modification, points similar to those of the first embodiment described above will be omitted, and points different from the first embodiment described above will be mainly described.

In the first embodiment described above, the power feed unit 22 that supplies a current is connected between the positive electrode tab B11 of the wound battery A and the negative electrode tab C11 of the wound battery A, and while not limited thereto, for example, a resistance 6 (see FIG. 9) as a power discharge unit for discharging the wound battery A may be connected.

In this case, by discharging the wound battery A, it is possible to generate a current flowing in the winding direction of the wound battery A similarly to the first embodiment described above. As similarly to the first embodiment described above, the detection unit 4 can detect a magnetic field generated by the current flowing in the winding direction of the wound battery A.

In the first embodiment described above, the detection unit 4 includes the first detection sensor 41 and the second detection sensor 42, but is not limited to this, and for example, may include only the first detection sensor 41, or may include a solenoid coil in place of the detection sensor.

In the first embodiment described above, the power feed unit 22 supplies the predetermined direct current to the wound battery A, but is not limited to this, and for example, may supply an alternating current to the wound battery A. In this case, the processing unit 24 determines connection quality of the connection part based on the ratio between the magnetic field detected by the detection unit 4 and the alternating current by the power feed unit 22 and the table. In this case, the table includes a magnitude range of the ratio between the magnetic field and the alternating current, the orientation of the magnetic field, and a plurality of electrode tabs with connection defects corresponding to both.

In this case, the detection unit 4 detects a magnetic field having the same frequency component in the alternating current supplied from the power feed unit 22. Then, the processing unit 24 determines connection quality of the connection part based on the magnetic field of the frequency component. For example, the processing unit 24 includes a lock-in amplifier, and specifically, noise is removed from the magnetic field having the same frequency component as the alternating current by the lock-in amplifier. Then, the processing unit 24 determines connection quality of the connection part based on the magnetic field of the frequency component from which the noise has been removed (the magnitude of the magnetic field of the frequency component and the orientation of the magnetic field of the frequency component).

According to this modification, by supplying an alternating current in place of a direct current to the wound battery A, as compared with a case of supplying a direct current to the wound battery A, it is possible to suppress generation of noise due to an external magnetic field or the like (e.g., a ground magnetic field) and improve detection accuracy, and therefore it is possible to more accurately detect connection quality of the connection part.

Furthermore, when the power feed unit 22 supplies an alternating current to the wound battery A sealed in the case, the frequency of the alternating current is preferably 10 kHz or less. This is because when the alternating current has a high frequency, there is a possibility that a magnetic field by the current flowing in the winding direction of the wound battery A cannot be detected from the outside of the case due to the magnetic shield effect by the case.

In the first embodiment described above, the first external electrode D1 and the second external electrode D2 are connected respectively to the lower surface of the positive electrode tab B11 positioned on the innermost peripheral side of the positive electrode tab group B1 and the lower surface of the negative electrode tab C11 positioned on the outermost peripheral side of the negative electrode tab group C1. However, the first external electrode D1 and the second external electrode D2 are not limited to this, and may be connected respectively to, for example, the lower surface of the positive electrode tab B11 positioned on the innermost peripheral side of the positive electrode tab group B1 and the upper surface of the negative electrode tab C11 positioned on the innermost peripheral side of the negative electrode tab group C1 (see FIGS. 10A to 11B).

In this case, as illustrated in FIGS. 10A and 101B, when a connection defect is generated in the negative electrode tab C11_6 positioned on the outermost peripheral side of the connection part where the plurality of electrodes and the external electrodes are connected in the wound battery A of the modification, a relatively small current I5 flowing counterclockwise (outer winding direction) of the wound battery A of the modification is generated, and a relatively small magnetic flux φ5 (i.e., the third magnetic field) in the axis negative direction of the wound battery A of the modification by the current I5 is generated. Here, the axis negative direction is a direction from the other end side of the wound battery A toward one end side of the wound battery A, and is also simply called a negative direction.

On the other hand, as illustrated in FIGS. 11A and 11B, when a connection defect is generated in the plurality of negative electrode tabs C11_4 to C11_6 positioned on the outer peripheral side of the connection part where the plurality of electrode tabs and the external electrodes are connected in the wound battery A of the modification, a current I6 greater than the current I5 flowing counterclockwise (outer winding direction) of the wound battery A of the modification is generated, and a magnetic flux φ6 (i.e., the third magnetic field) greater than the magnetic flux φ5 in the negative direction of the wound battery A of the modification due to the current I6 is generated.

### Second Embodiment

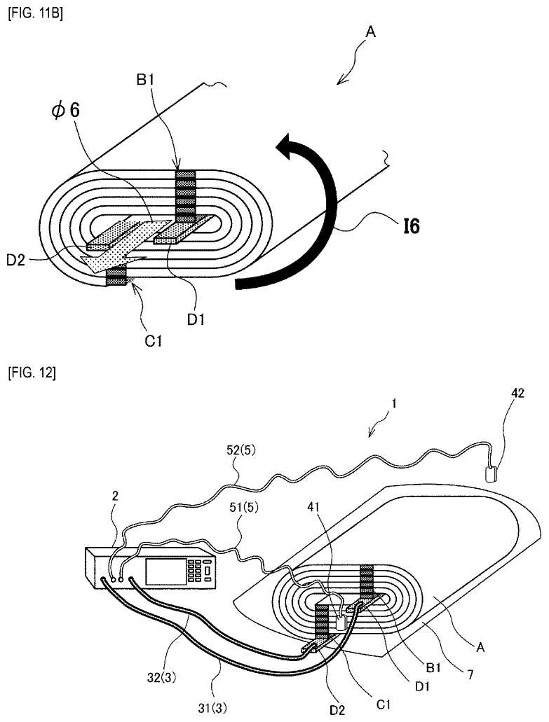

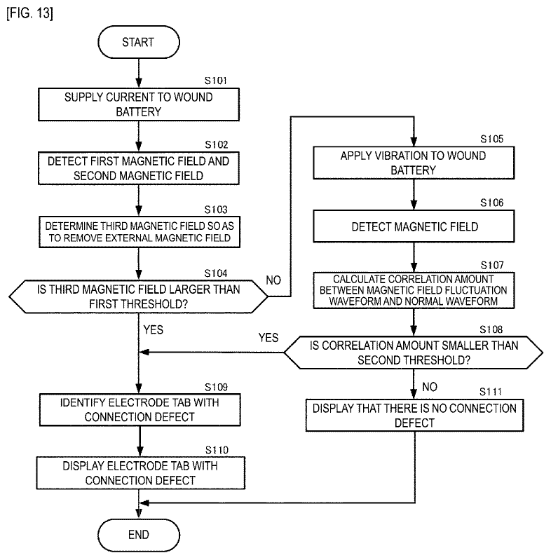

Hereinafter, the detection system 1 and the detection method according to the second embodiment will be described with reference to FIGS. 12 and 13. Note that in the second embodiment, points matching those of the first embodiment described above will be omitted, and points different from the first embodiment described above will be mainly described.

### [Configuration of Detection System]

Next, the detection system 1 according to the second embodiment will be described with reference to FIG. 12.

FIG. 12 is a schematic explanatory diagram illustrating each configuration of the detection system 1 according to the second embodiment.

In the first embodiment described above, the detection system 1 includes the detection device 2, the current wiring 3, the detection unit 4, and the detection wiring 5, on the other hand, as illustrated in FIG. 12, in the second embodiment, the detection system 1 further includes a vibration table 7 as an application mechanism in addition to the detection device 2, the current wiring 3, the detection unit 4, and the detection wiring 5. Note that in the second embodiment, the application mechanism includes the vibration table 7, and while not limited thereto, the application mechanism may include, for example, a mechanism having a function of applying an impact to the wound battery A.

As illustrated in FIG. 12, the wound battery A is fixed to the vibration table 7. This enables the vibration table 7 to apply vibration having a predetermined amplitude and a predetermined frequency to the wound battery A. The vibration table 7 and the detection device 2 are electrically connected. This enables the operation of the vibration table 7 to be controlled by the processing unit 24 (see FIG. 3) of the detection device 2.

Note that in the second embodiment, the vibration table 7 is configured to be controlled by the processing unit 24, but is not limited to this, and for example, may be configured to be controlled by a controller incorporated in the vibration table 7.

In the first embodiment described above, the storage 23 of the detection device 2 stores a predetermined direct current, a predetermined threshold, and a table, whereas in the second embodiment, the storage 23 further stores a predetermined frequency used for the operation of the vibration table 7, a normal waveform as a normal parameter used for the determination processing of connection quality by the processing unit 24, and a second threshold in addition to the predetermined direct current, a first threshold, which is the same as the predetermined threshold, and the table (see FIG. 3).

### [Detection Method by Detection System]

Next, the detection method by the detection system 1 according to the second embodiment will be described with reference to FIG. 13.

FIG. 13 is a flowchart showing each step of the detection method by the detection system 1 according to the second embodiment.

In the first embodiment described above, the detection method by the detection system 1 includes steps S1 to S7, and on the other hand, as shown in FIG. 13, in the second embodiment, the detection method includes steps S101 to S111. Note that steps S101 to S103 and steps S109 to S111 in the second embodiment match steps S1 to S3 and steps S5 to S7 in the first embodiment, respectively, and thus descriptions thereof will be omitted.

As shown in FIG. 13, in step S104, the processing unit 24 determines whether or not the magnitude (absolute value) of the third magnetic field is greater than the first threshold (value greater than zero) stored in the storage 23 in advance. Then, if the magnitude of the third magnetic field is greater than the predetermined threshold (case of Yes), the processing unit 24 determines that the connection of the connection part is defective, and the process proceeds to step S109. On the other hand, if the magnitude of the third magnetic field is the first threshold or less (case of No), the process proceeds to step S105.

Next, in step S105, the vibration table 7 applies vibration having a predetermined frequency to the wound battery A. Specifically, in step S105, the processing unit 24 generates and outputs, to the vibration table 7, a control signal for vibrating the vibration table 7. Then, the vibration table 7 applies vibration having a predetermined frequency to the wound battery A based on the control signal output from the processing unit 24, and the process proceeds to step S106.

Next, in step S106, the first detection sensor 41 detects a magnetic field at the time of vibration as a second magnetic field-related parameter in a state where vibration is applied to the wound battery A. Then, the first detection sensor 41 outputs the detected magnetic field at the time of vibration to the processing unit 24 via the input interface 21, and the process proceeds to step S107.

Next, in step S107, the processing unit 24 acquires a magnetic field fluctuation waveform as a magnetic field fluctuation parameter based on the magnetic field at the time of vibration output from the first detection sensor 41. Then, the processing unit 24 calculates a correlation amount between the acquired magnetic field fluctuation waveform and the normal waveform stored in the storage 23 in advance, and the process proceeds to step S108. Note that the normal waveform is, for example, a waveform when the connection of the connection part is good detected by the first detection sensor 41 at the time of vibration.

Next, in step S108, the processing unit 24 determines connection quality of the connection part (specifically, the plurality of positive electrode tabs B11 and the plurality of negative electrode tabs C11) based on the correlation amount.

Specifically, in step S108, the processing unit 24 determines contact quality of the connection part based on the correlation amount and the second threshold (value greater than zero) stored in the storage 23 in advance. Then, if the correlation amount is less than the second threshold (case of Yes), the processing unit 24 determines that the connection of the connection part is defective, and the process proceeds to step S109. On the other hand, if the correlation amount is the second threshold or more (case of No), the processing unit 24 determines that the connection of the connection part is good, notifies the display unit 25 of the determined goodness of the connection part, and the process proceeds to step S111. By this, even in a state where the resistance value of the wound battery A is low, it is possible to accurately detect the connection quality of the connection part, and therefore it is possible to further improve the detection accuracy of detecting connection quality of the connection part.

On the other hand, when the process proceeds from step S104 to step S109, that is, when the processing unit 24 determines that the connection of the connection part is defective before applying vibration to the wound battery A, steps S105 to S108 (i.e., steps such as vibration) can be skipped, and therefore the operation of the detection system 1 can be simplified while improving the detection accuracy of the detection system 1.

### Actions and Effects of Second Embodiment

Next, main actions and effects according to the second embodiment will be described.

In the second embodiment, the detection system 1 further includes the vibration table 7 that applies vibration to the wound battery A in addition to the power feed unit 22, the detection unit 4, and the processing unit 24, the detection unit 4 detects a magnetic field (first magnetic field-related parameter) in a state where no vibration is applied to the wound battery A and a magnetic field at the time of vibration (second magnetic field-related parameter) in a state where vibration is applied to the wound battery A, and the processing unit 24 determines connection quality of the connection part based on the detected magnetic field and the magnetic field at the time of vibration.

According to this configuration, in addition to the magnetic field in a state where no vibration is applied to the wound battery A, the magnetic field at the time of vibration is used for determination of connection quality of the connection part, and therefore, even in a state where the resistance value of the wound battery A is low, it is possible to accurately detect the connection quality of the connection part. As a result, it is possible to further improve detection accuracy of detecting connection quality of the connection part.

In the second embodiment, the processing unit 24 acquires a magnetic field fluctuation waveform based on the magnetic field at the time of vibration, calculates the correlation amount between the magnetic field fluctuation waveform and the normal waveform, determines that the connection of the connection part is good if the magnitude (absolute value) of the magnetic field is the first threshold or less and the correlation amount is the second threshold or more, and determines that the connection of the connection part is defective if the magnitude (absolute value) of the magnetic field is greater than the first threshold or the correlation amount is less than the second threshold.

According to this configuration, use of both the first threshold and the second threshold enables connection quality of the connection part to be detected more accurately.

### Modification of Second Embodiment

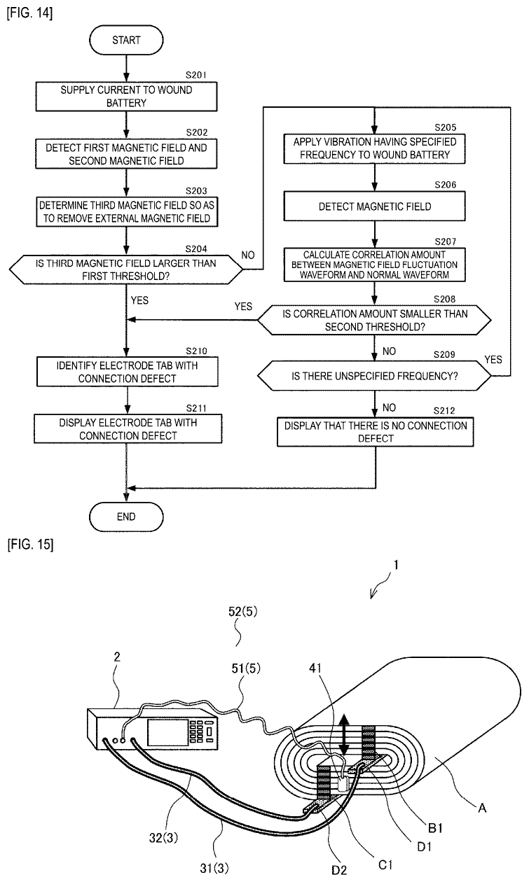

Next, the detection system 1 and the detection method according to the modification of the second embodiment will be described with reference to FIG. 14. Note that in the present modification, points matching those of the second embodiment described above will be omitted, and points different from the second embodiment described above will be mainly described.

FIG. 14 is a flowchart showing each step of the detection method according to the modification of the second embodiment.

In the second embodiment described above, the storage 23 stores a predetermined direct current, a single first threshold, a single predetermined frequency, a single second threshold, a single normal waveform, and a table, and on the other hand, in the present modification, the storage stores a predetermined direct current, a single first threshold, a plurality of frequencies that change stepwise, a plurality of second thresholds, a plurality of normal waveforms, and a table. Note that the plurality of frequencies, the plurality of second thresholds, and the plurality of normal waveforms are associated with one another.

In the second embodiment described above, the detection method includes steps S101 to S111, whereas in the present modification, the detection method includes steps S201 to S212. Note that steps S201 to S204 and steps S210 to S212 in the present modification match steps S101 to S104 and steps S109 to S111 in the second embodiment, respectively, and thus descriptions thereof will be omitted.

As shown in FIG. 14, in step S205, the vibration table 7 applies vibration having a specified frequency to the wound battery A. Specifically, in step S205, the processing unit 24 specifies the frequency of the vibration table 7 (e.g., first, specifies a frequency having the smallest frequency from a plurality of frequencies, and then switch and specifies the frequencies in descending order), and generates and outputs, to the vibration table 7, a control signal for vibrating the vibration table 7 at the specified frequency. Then, the vibration table 7 applies vibration having the specified frequency to the wound battery A based on the control signal output from the processing unit 24, and the process proceeds to step S206.

Next, in step S206, the first detection sensor 41 detects a magnetic field at the time of vibration in a state where the vibration whose frequency has been specified is applied to the wound battery A. Then, the first detection sensor 41 outputs the detected magnetic field at the time of vibration to the processing unit 24 via the input interface 21, and the process proceeds to step S107.

Next, in step S207, the processing unit 24 acquires the magnetic field fluctuation waveform based on the magnetic field at the time of vibration output from the first detection sensor 41. Then, the processing unit 24 calculates the correlation amount between the acquired magnetic field fluctuation waveform and the normal waveform associated with the specified frequency, and the process proceeds to step S208.

Next, in step S208, the processing unit 24 determines whether or not the correlation amount is less than the second threshold (value greater than zero) associated with the specified frequency. Then, if the correlation amount is less than the second threshold (case of Yes), the processing unit 24 determines that the connection of the connection part is defective, and the process proceeds to step S210. On the other hand, if the correlation amount is the second threshold or more (case of No), the process proceeds to step S209.

Next, in step S209, the processing unit 24 determines whether or not there is an unspecified frequency. Then, if there is an unspecified frequency (case of Yes), the process returns to step S205. On the other hand, if there is no unspecified frequency (case of No), the process proceeds to step S212.

That is, if the magnitude (absolute value) of the magnetic field is the first threshold or less and the correlation amount is the second threshold or more at all frequencies, the processing unit 24 determines that the connection of the connection part is good. Conversely, if the correlation amount of any of the plurality of frequencies is less than the second threshold, the processing unit 24 determines that the connection of the connection part is defective. This can further improve the detection accuracy of detecting connection quality of the connection part as compared with the case of vibrating the wound battery A at a single frequency.

In the present modification, the vibration table 7 applies vibration having a variable frequency to the wound battery A, and the processing unit 24 acquires, for each frequency, the magnetic field fluctuation waveform based on the magnetic field at the time of vibration (second magnetic field-related parameter), calculates, for each frequency, the correlation amount between the magnetic field fluctuation waveform and the normal waveform, and determines that the connection of the connection part is good if the magnitude (absolute value) of the magnetic field is the first threshold or less and the correlation amount is the second threshold or more at all frequencies.

According to this configuration, it is possible to further improve the detection accuracy of detecting connection quality of the connection part as compared with the case of vibrating the wound battery A at a single frequency.

In the second embodiment described above, the power feed unit 22 that supplies a current is connected between the positive electrode tab B11 of the wound battery A and the negative electrode tab C11 of the wound battery A, and while not limited thereto, for example, a resistance 6 (see FIG. 9) for discharging the wound battery A may be connected.

In the modification of the second embodiment described above, vibration changes stepwise at a plurality of frequencies, but is not limited to this, and may change at random, for example. In this case, the detection system 1 further includes a frequency detection unit (not illustrated) that detects the frequency of vibration applied to the wound battery A. Then, the detection unit 4 detects the magnetic field for each detected frequency.

### Third Embodiment

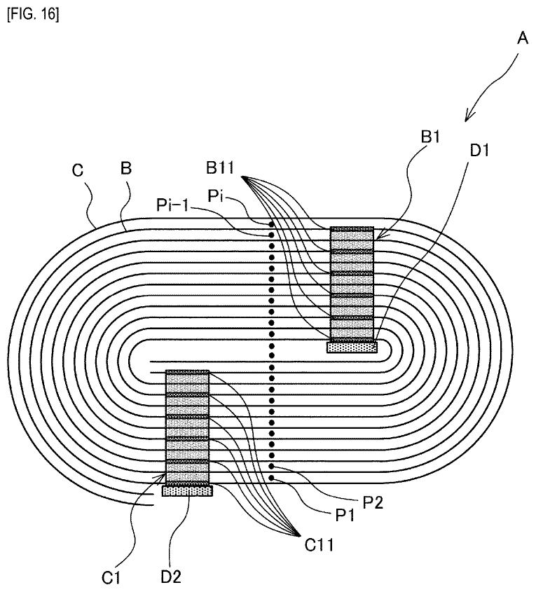

Hereinafter, the detection system 1 and the detection method according to the third embodiment will be described with reference to FIGS. 15 to 19. Note that in the third embodiment, points matching those of the first embodiment described above will be omitted, and points different from the first embodiment described above will be mainly described.

### [Configuration of Detection System]

Next, the detection system 1 according to the third embodiment will be described with reference to FIGS. 15 and 16.

FIG. 15 is a schematic explanatory diagram illustrating each configuration of the detection system 1 according to the third embodiment. FIG. 16 is a schematic explanatory diagram illustrating an example of a plurality of detection points according to the third embodiment.

In the first embodiment described above, the detection unit 4 includes the first detection sensor 41 and the second detection sensor 42, meanwhile, as illustrated in FIG. 15, in the third embodiment, the detection unit 4 includes only the first detection sensor 41. In this case, as indicated by an arrow in FIG. 15, for example, the magnetic field is detected at a plurality of detection points while moving the first detection sensor 41 (FIG. 16).

Note that in the third embodiment, as illustrated in FIG. 16, the plurality of (i) detection points (specifically, detection points P1, P2, . . . , Pi−1, Pi) are arrayed at predetermined intervals (equal intervals) along the vertical direction so as to be positioned between (in the middle of) the plurality of positive electrode layers B and the plurality of negative electrode layers C. However, the plurality of detection points are not limited to this, and for example, may be arrayed at intervals along the horizontal direction or may be configured to be arranged at intervals along a direction inclined with respect to the horizontal direction.

In the third embodiment, the first detection sensor 41 includes a single first detection sensor that detects a magnetic field while moving between a plurality of detection points, and while not limited thereto, for example, a plurality of first detection sensors that are respectively provided at a plurality of detection points in advance and detect a magnetic field may be included.

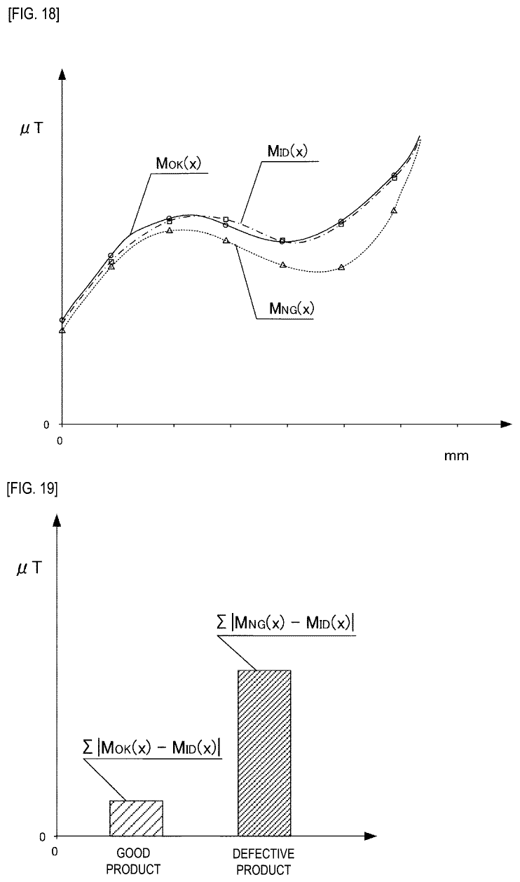

In the first embodiment described above, the storage 23 of the detection device 2 stores a predetermined direct current, a predetermined threshold, and a table, whereas in the third embodiment, the storage 23 further stores an ideal characteristic graph M_{ID}(x) as an ideal characteristic parameter used for determination processing of connection quality by the processing unit 24 and an addition threshold as a matching degree threshold, in addition to the predetermined direct current. Here, the ideal characteristic graph M_{ID}(x) is a characteristic curve indicating, in an ideal state, position information (i.e., the distance between a reference position and the detection points) of the plurality of (i) detection points and a magnetic field M_{ID} (specifically, magnetic flux density) as a plurality of magnetic field-related parameters associated with respective pieces of position information on the plurality of (i) detection points (see FIG. 18), where x=1, 2, . . . , i−1, i. Note that in the third embodiment, the reference position includes the detection point P1 positioned lowermost (see FIG. 16), but is not limited to this, and may include, for example, the detection point Pi positioned uppermost.

### [Detection Method by Detection System]

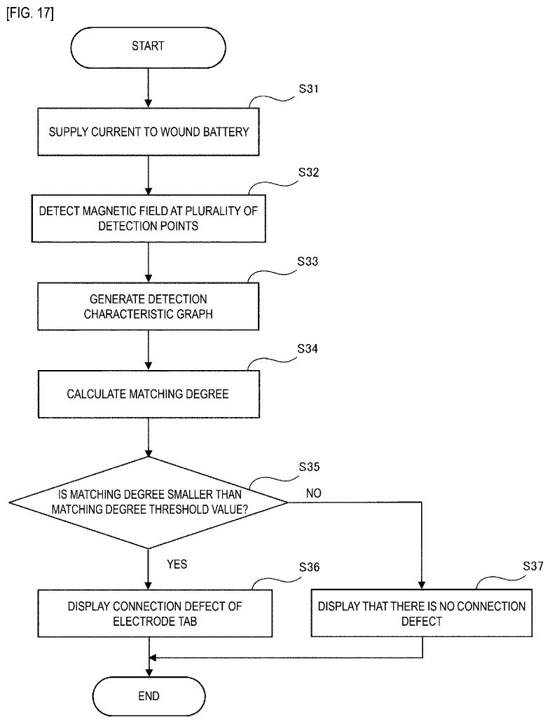

Next, the detection method by the detection system 1 according to the third embodiment will be described with reference to FIGS. 17 to 19.

FIG. 17 is a flowchart showing each step of the detection method by the detection system 1 according to the third embodiment. FIG. 18 is a comparison graph showing three of the ideal characteristic graph M_{ID}(x), a good product characteristic graph M_{OK}(x), and a defective product characteristic graph M_{NG}(x), where x=1, 2, . . . , i−1, i. Note that in FIG. 18, position information (mm) of the detection point and the magnetic field M (specifically, magnetic flux density/μT) are on the horizontal axis and the vertical axis, respectively. FIG. 19 is an explanatory diagram illustrating an example of calculation of the matching degree, and illustrates an addition Σ|M_{OK}(x)−M_{ID}(x)| of the absolute value of a difference between the good product characteristic graph M_{OK}(x) of a good product and the ideal characteristic graph M_{ID}(x), and an addition Σ|M_{NG}(x)−M_{ID}(x)| of the absolute value of a difference between the defective product characteristic graph M_{NG}(x) of the defective product and the ideal characteristic graph M_{ID}(x), where x=1, 2, . . . , i−1, i. Note that in FIG. 19, the magnetic field M (specifically, magnetic flux density/μT) is on the vertical axis.

In the first embodiment described above, the detection method by the detection system 1 includes steps S1 to S7, and on the other hand, as shown in FIG. 17, in the third embodiment, the detection method includes steps S31 to S37. Note that step S31 and step S37 in the third embodiment match step S1 and step S7 in the first embodiment, respectively, and thus descriptions thereof will be omitted.

As shown in FIG. 17, in step S32, the first detection sensor 41 detects a magnetic field by the current flowing in the winding direction of the wound battery A at a plurality of detection points. Then, the first detection sensor 41 outputs the plurality of detected magnetic fields to the processing unit 24 via the input interface 21, and the process proceeds to step S33.

Next, in step S33, the processing unit 24 generates a detection characteristic graph as a detection characteristic parameter based on the position information on the plurality of detection points and the plurality of magnetic fields (specifically, the plurality of magnetic fields associated with respective pieces of position information on the plurality of detection points) output from the first detection sensor 41, and the process proceeds to step S34.

Here, as illustrated in FIG. 18, the detection characteristic graph generated by the processing unit 24 includes both the good product characteristic graph M_{OK}(x) and the defective product characteristic graph M_{NG}(x). Note that the good product characteristic graph M_{OK}(x) is a characteristic curve indicating, in a state where the connection of the connection part is good, the position information on the plurality of (i) detection points and the plurality of magnetic fields MOK associated with respective pieces of position information on the plurality of (i) detection points. The defective product characteristic graph M_{NG}(x) is a characteristic curve indicating, in a state where the connection of the connection part is defective, the position information on the plurality of (i) detection points and the plurality of magnetic fields M_{NG} associated with respective pieces of position information on the plurality of (i) detection points. Where x=1, 2, . . . , i−1, i.

Next, in step S34, the processing unit 24 calculates, based on the detection characteristic graph generated and the ideal characteristic graph M_{ID}(i), a matching degree between both (e.g., addition of the absolute value of the difference between the detection characteristic graph and the ideal characteristic graph M_{ID}(i), hereinafter, also simply called “difference absolute value addition”), and the process proceeds to step S35.

Here, as illustrated in FIG. 19, the addition of the absolute value of the difference between the detection characteristic graph calculated by the processing unit 24 and the ideal characteristic graph M_{ID}(x) includes the addition Σ|M_{OK}(x)−M_{ID}(x)| of the absolute value of the difference between the good characteristic graph M_{OK}(x) of the good product and the ideal characteristic graph M_{ID}(x), and the addition Σ|M_{NG}(x)−M_{ID}(x)| of the absolute value of the difference between the defective product characteristic graph M_{NG}(x) of the defective product and the ideal characteristic graph M_{ID}(x), where x=1, 2, . . . , i−1, i.

Next, in step S35, the processing unit 24 determines connection quality of the connection part based on the difference absolute value addition and the addition threshold stored in the storage 23 in advance.

Then, if the difference absolute value addition is greater than the addition threshold (case of Yes), that is, if the matching degree is less than the matching degree threshold, the processing unit 24 determines that the connection of the connection part is defective, and the process proceeds to step S36. On the other hand, if the difference absolute value addition is the addition threshold or less (case of No), that is, if the matching degree is the matching degree threshold or more, the processing unit 24 determines that the connection of the connection part is defective, and the process proceeds to step S37.

By this, since the magnetic fields at the plurality of detection points by the current flowing in the winding direction of the wound battery A are used for determination of connection quality of the connection part, even when the magnetic field generated by the defect of the connection part is small, it is possible to accurately detect the connection quality of the connection part. As a result, it is possible to further improve detection accuracy of detecting connection quality of the connection part.

Next, in step S36, the display unit 25 displays connection defect of the electrode tab output from the processing unit 24, and ends the present processing.

In the third embodiment described above, the matching degree between the detection characteristic parameter and the ideal characteristic parameter is realized by the difference absolute value addition described above, but is not limited to this, and may be realized by another calculation or the like.

In the third embodiment described above, the power feed unit 22 that supplies a current is connected between the positive electrode tab B11 of the wound battery A and the negative electrode tab C11 of the wound battery A, and while not limited thereto, for example, a resistance 6 (see FIG. 9) for discharging the wound battery A may be connected.

### Actions and Effects of Third Embodiment

Next, main actions and effects according to the third embodiment will be described.

In the third embodiment, the detection unit 4 detects the magnetic field at a plurality of detection points, and the processing unit 24 generates the detection characteristic graph based on the position information on the plurality of detection points and the plurality of magnetic field-related parameters associated with respective pieces of position information on the plurality of detection points, calculates the difference absolute value addition between the detection characteristic graph and the ideal characteristic graph M_{ID}(x), and determines connection quality of the connection part based on the difference absolute value addition.

According to this configuration, since the magnetic fields at the plurality of detection points by the current flowing in the winding direction of the wound battery A are used for determination of connection quality of the connection part, even when the magnetic field generated by the defect of the connection part is small, it is possible to accurately detect the connection quality of the connection part. As a result, it is possible to further improve detection accuracy of detecting connection quality of the connection part.

In the third embodiment, the processing unit 24 determines that the connection of the connection part is good if the difference absolute value addition is the addition threshold or less, and determines that the connection of the connection part is defective if the difference absolute value addition is greater than the addition threshold.

According to this configuration, by using the addition threshold, it is possible to accurately detect the connection quality of the connection part.

The present application claims priority based on Japanese Patent Application No. 2022-149275 filed with the Japanese Patent Office on Sep. 20, 2022 and priority based on Japanese Patent Application No. 2023-143973 filed with the Japanese Patent Office on Sep. 5, 2023, the entire contents of which are incorporated herein by reference.

While the embodiments and the modifications have been described above, the embodiments described above and the modifications merely illustrate a part of an application example of the present invention, and it is not intended to limit the technical scope of the present invention to the specific configuration of the embodiments described above.

### REFERENCE SIGNS LIST

1 detection system
3 current wiring
4 detection unit
5 detection wiring
6 resistance (power discharge unit)
22 power feed unit
24 processing unit
41 first detection unit
42 second detection unit
A wound battery
B111 positive electrode tab
C11 negative electrode tab

1. A detection system that detects connection quality of a connection part where a plurality of electrode tabs and external electrodes are connected in a wound battery, the detection system comprising:
a power feed unit or a power discharge unit configured to perform power feed or power discharge between a positive electrode tab of the wound battery and a negative electrode tab of the wound battery;
a detection unit configured to detect a magnetic field-related parameter resulting from power feed to the wound battery or power discharge from the wound battery; and
a processing unit configured to determine connection quality of the connection part based on the magnetic field-related parameter that is detected.

2. The detection system according to claim 1, wherein
the processing unit determines that connection of the connection part is good if an absolute value of the magnetic field-related parameter is equal to or less than a predetermined threshold, and determines that connection of the connection part is defective if an absolute value of the magnetic field-related parameter is greater than a predetermined threshold.

3. The detection system according to claim 1, wherein
the power feed unit supplies a direct current between the positive electrode tab of the wound battery and the negative electrode tab of the wound battery,
the detection unit includes
a first detection unit that is provided in proximity to the wound battery and detects a magnetic field, and
a second detection unit that is provided farther away from the wound battery than the first detection unit and detects an external magnetic field, and
the processing unit determines connection quality of the connection part based on the magnetic field and the external magnetic field that are detected.

4. The detection system according to claim 1 further comprising:
a current wiring including a four-terminal pair measurement structure wiring, a twist wiring, a coaxial wiring, or a magnetic shield wiring, the current wiring connecting the power feed unit or the power discharge unit and the positive electrode tab or the negative electrode tab.

5. The detection system according to claim 1 further comprising:
a detection wiring including a four-terminal pair measurement structure wiring, a twist wiring, a coaxial wiring, or a magnetic shield wiring,
the detection wiring connecting the detection unit and the processing unit.

6. The detection system according to claim 1, wherein
the detection unit detects a magnetic field generated by a current flowing in a winding direction of the wound battery.

7. The detection system according to claim 1, wherein
when the power feed unit is connected between a positive electrode tab of the wound battery and a negative electrode tab of the wound battery,
the power feed unit supplies an alternating current between the positive electrode tab of the wound battery and the negative electrode tab of the wound battery,
the detection unit detects a magnetic field of an identical frequency component in the alternating current, and
the processing unit determines connection quality of the connection part based on the magnetic field of the frequency component.

8. The detection system according to claim 1, wherein
the wound battery is sealed in a case,
when the power feed unit is connected between a positive electrode tab of the wound battery and a negative electrode tab of the wound battery,
the power feed unit supplies an alternating current between the positive electrode tab of the wound battery and the negative electrode tab of the wound battery, and
a frequency of the alternating current is equal to or less than 10 kHz.

9. The detection system according to claim 1, wherein
the processing unit identifies that the electrode tab with a connection defect is closer to the external electrode as the magnetic field-related parameter is greater if a magnitude of the magnetic field-related parameter that is detected is greater than a predetermined threshold.

10. The detection system according to claim 1, wherein
the processing unit identifies whether the electrode tab with a connection defect is positive or negative based on an orientation of the magnetic field-related parameter if a magnitude of the magnetic field-related parameter that is detected is greater than a predetermined threshold.

11. The detection system according to claim 1, wherein
the processing unit identifies the electrode tab with a connection defect based on a magnitude of the magnetic field-related parameter and an orientation of the magnetic field-related parameter if a magnitude of the magnetic field-related parameter that is detected is greater than a predetermined threshold.

12. The detection system according to claim 1, wherein
the power feed unit and the processing unit are integrally formed.

13. The detection system according to claim 1 further comprising
an application mechanism configured to apply vibration or impact to the wound battery, wherein
the detection unit detects a first magnetic field-related parameter as the magnetic field-related parameter in a state where vibration or impact is not applied to the wound battery and a second magnetic field-related parameter as the magnetic field-related parameter in a state where vibration or impact is applied to the wound battery, and
the processing unit determines connection quality of the connection part based on the first magnetic field-related parameter and the second magnetic field-related parameter that are detected.

14. The detection system according to claim 13, wherein
the processing unit
acquires a magnetic field fluctuation waveform based on the second magnetic field-related parameter, and calculates a correlation amount between the magnetic field fluctuation waveform and a normal waveform,
determines that connection of the connection part is good if an absolute value of the magnetic field-related parameter is equal to or less than a first threshold and the correlation amount is equal to or greater than a second threshold, and
determines that connection of the connection part is defective if an absolute value of the first magnetic field-related parameter is greater than a first threshold or if the correlation amount is less than a second threshold.

15. The detection system according to claim 13, wherein
the application mechanism applies vibration having a variable frequency to the wound battery, and
the processing unit
acquires, for each frequency, a magnetic field fluctuation parameter based on the second magnetic field-related parameter, and calculates, for each frequency, a correlation amount between the magnetic field fluctuation parameter and a normal parameter, and
determines that connection of the connection part is good if an absolute value of the first magnetic field-related parameter is equal to or less than a first threshold and the correlation amount is equal to or greater than a second threshold at all frequencies.

16. The detection system according to claim 15 further comprising:
a frequency detection unit configured to detect a frequency of vibration applied to the wound battery, wherein
the detection unit detects the second magnetic field-related parameter for each frequency detected.

17. The detection system according to claim 1, wherein
the detection unit detects the magnetic field-related parameter at a plurality of detection points, and
the processing unit
generates a detection characteristic parameter based on position information on the plurality of detection points and a plurality of the magnetic field-related parameters associated with respective pieces of position information on the plurality of detection points, and calculates a matching degree between the detection characteristic parameter and an ideal characteristic parameter, and
determines connection quality of the connection part based on the matching degree.

18. The detection system according to claim 17, wherein
the processing unit determines that connection of the connection part is good if the matching degree is equal to or greater than a matching degree threshold, and determines that connection of the connection part is defective if the matching degree is less than a matching degree threshold.

19. A detection method for detecting connection quality of a connection part where a plurality of electrode tabs and external electrodes are connected in a wound battery, the detection method comprising:
a power feed or power discharge step of performing power feed or power discharge between a positive electrode tab of the wound battery and a negative electrode tab of the wound battery;
a detection step of detecting a magnetic field-related parameter resulting from power feed to the wound battery or power discharge from the wound battery; and
a determination step of determining connection quality of the connection part based on the magnetic field-related parameter that is detected.
